(19) United States
(12) Patent Application Publication
(10) Pub. No.: US 2011/0068467 A1
(43) Pub. Date: Mar. 24, 2011

(54) Semiconductor device and method of manufacturing same

(75) Inventor: Masahiro Ozaki, Kanagawa (JP)

(73) Assignee: Renesas Electronics Corporation, Kawasaki-shi (JP)

(21) Appl. No.: 12/923,404

(22) Filed: Sep. 20, 2010

(30) Foreign Application Priority Data
Sep. 24, 2009 (JP) 2009-219645

(51) Int. Cl. H01L 23/48; H01L 21/50

(52) U.S. Cl. 257/737; 438/108; 257/778; 257/E23.021; 257/E21.499

(57) ABSTRACT

A semiconductor device includes the semiconductor chip connected in a flip-chip style to the substrate, and the underfill resin formed between the substrate and the semiconductor chip and including a filet, wherein the underfill resin includes a first resin layer and a second resin layer superposed on each other in at least a part of a region overlapping with the semiconductor chip in a plan view, and at least one of the first and the second resin layer is formed over an area including the region overlapping with said semiconductor chip in a plan view and the filet.

This application is based on Japanese patent application No. 2009-219645, the content of which is incorporated hereinto by reference.

### BACKGROUND

1. Technical Field

The present invention relates to a semiconductor device and a method of manufacturing the same, and more particularly to a semiconductor device that includes an underfill resin provided between a semiconductor chip mounted in a flip-chip style and a substrate, and to a method of manufacturing such semiconductor device.

2. Related Art

A flip-chip connection is widely employed to mount a semiconductor chip on a substrate a, which includes disposing the semiconductor chip such that the element-carrying surface thereof confronts the substrate, and electrically connecting pads of the semiconductor chip and the substrate, through bumps such as solder balls. In such configuration, an underfill resin is provided between the semiconductor chip and the substrate, in order to assure the effective connection and to protect the connection points. The underfill resin includes a filet formed around the semiconductor chip, to thereby enhance the bonding strength between the semiconductor chip and the substrate.

Japanese Laid-Open Utility Publication No. 2001-102414 discloses a technique of heat-pressing a portion of a resin film extending off an outer periphery of the semiconductor chip, at the same time as heat-pressing the semiconductor chip on an interconnect pattern on the circuit substrate with the resin film disposed therebetween, to thereby form the filet of the resin film around lateral faces of the semiconductor chip.

It is difficult with the conventional technique, however, to form the filet in a uniform shape around the semiconductor chip, attaining at the same time the advantage of enhanced bonding strength of the underfill resin between the substrate and the semiconductor chip. For example, it is preferable that the substrate and the underfill resin have close thermal expansion coefficients, in order to enhance the bonding strength of the underfill resin between the substrate and the semiconductor chip. This is because the substrate and the underfill resin exhibit similar behavior in the case where these have close thermal expansion coefficients, even though the substrate and the underfill resin expand or contract after the underfill resin has cured, which leads to enhancing the bonding strength between the substrate and the underfill resin.

On the other hand, to form the filet in a uniform shape in all directions around the semiconductor chip, to thereby attain uniform stress of the underfill resin, it is preferable, for example, to employ an underfill resin that is relatively soft, in a state before curing. However it has so far been difficult to prepare an underfill resin that satisfies the plurality of characteristics described above.

Japanese Laid-Open Utility Publication No. 2008-103700 discloses a semiconductor device including an adhesive film for semiconductor, in which components of the film are separated in two layers, in a cross-sectional view after a dibond sheet has cured. This document also discloses employing a multilayer dibond sheet, which has a multilayer structure.

Japanese Laid-Open Utility Publication No. 2003-176461 discloses an ACA film of a three-layer structure, including a main ACA film containing an epoxy resin as the base, non-conductive particles of a size of 0.1 to 1 μm, and conductive particles of a size of 3 to 10 μm, or a main ACA film containing only the conductive particles of a size of 3 to 10 μm; and an adhesive enhancing layer containing an epoxy resin as the base and formed on the respective sides of the main ACA film.

Japanese Laid-Open Utility Publication No. 2000-299414 discloses a flip-chip style semiconductor device including an underfill material loaded in a gap between the substrate and the semiconductor chip, and a filet formed so as to encapsulate lateral faces of the semiconductor chip, in which the underfill material is an epoxy resin composition of 20 to 40 ppm/° C. in expansion coefficient under glass transition temperature, and the filet material is an epoxy resin composition of 20 ppm/° C. or lower in expansion coefficient under glass transition temperature.

Employing a plurality of types of resin as disclosed in the patented documents, Japanese Laid-Open Utility Publication No. 2008-103700, Japanese Laid-Open Utility Publication No. 2003-176461, and Japanese Laid-Open Utility Publication No. 2000-299414, appears to facilitate the control for satisfying the plurality of characteristics, compared with the case of employing a single resin. However, the techniques according to the patented documents of Japanese Laid-Open Utility Publication No. 2008-103700 and Japanese Laid-Open Utility Publication No. 2003-176461, the underfill resin does not include the filet, and a method of forming the filet in a desirable shape is not provided either.

Also, the technique according to the patented document of Japanese Laid-Open Utility Publication No. 2000-299414 employs different resins in the region between the substrate and the semiconductor chip and in the filet, and the resin composing the filet is provided alone only around the semiconductor chip. Such structure, however, still has a drawback in that stress of the resin composing the filet, arising from the expansion or contraction of the substrate and the underfill resin after the curing of the underfill resin, is only locally generated, which leads to compromise in the enhancing effect of the bonding strength between the substrate and the underfill resin. Besides, it is difficult to form the filet in a stable shape only around the lateral faces of the semiconductor chip.

### SUMMARY

According to the present invention, there is provided a semiconductor device comprising:

a substrate with a pad formed on a surface thereof;

a semiconductor chip mounted on the surface of the substrate such that an element-carrying surface thereof on which a bump is provided confronts the surface, and connected in a flip-chip style to the pad, through the bump; and

an underfill resin formed on the surface of the substrate in a region between the surface of the substrate and the semiconductor chip, and including a filet formed around the semiconductor chip on the surface of the substrate;

wherein the underfill resin includes a first resin layer constituted of a first resin composition and a second resin layer constituted of a second resin composition; the first resin layer and the second resin layer being superposed on each other in at least a part of a region overlapping with the semiconductor chip in a plan view; and at least one of the first resin layer and the second resin layer is formed over an area including the region overlapping with the semiconductor chip in a plan view and the filet.

According to the present invention, there is provided a method of manufacturing the foregoing semiconductor device, comprising:

disposing on the surface of the substrate one of the first resin composition to constitute the first resin layer and the second resin composition to constitute the second resin layer, the other of the first resin composition and the second resin composition, and the semiconductor chip, such that one of the first resin composition and the second resin composition, the other thereof, and the semiconductor chip are to be stacked in this order; and

connecting the pad of the substrate and the bump of the semiconductor chip by heat-pressing, and curing the first resin composition and the second resin composition thereby forming the underfill resin.

With such configuration, since the underfill resin is constituted of the plurality of resin layers, the resin materials can be appropriately selected according to desired characteristics. Also, the resin layer constituting at least one of the first resin layer and the second resin layer is provided over the area including the filet and the region overlapping with the semiconductor chip in a plan view. Such structure allows dispersing, in an in-plane direction of the substrate, a stress of the resin layer arising from expansion or contraction of the substrate and the underfill resin resultant from the curing of the underfill resin, for example in the case where an appropriate material for forming the filet in a desirable shape is employed for the resin layer. Meanwhile regarding the other resin layer, for example employing a material having a thermal expansion coefficient close to that of the substrate enables enhancing the bonding strength between the substrate and the underfill resin. Consequently, the foregoing structure allows, in the flip-chip connection of the semiconductor chip to the substrate, stably forming the filet of the underfill resin in a uniform shape, attaining at the same time the enhanced bonding strength.

It is to be noted that a different combination of the foregoing constituents, and a conversion of the expression of the present invention between a method and a device are also included in the scope of the present invention.

Thus, the present invention allows, in flip-chip connection of a semiconductor chip to a substrate, stably forming a filet of an underfill resin in a uniform shape, attaining at the same time enhanced bonding strength.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view showing a structure of a semiconductor device according to an embodiment of the present invention;

FIG. 2 is a plan view showing a structure of the semiconductor device according to the embodiment of the present invention;

FIGS. 3A to 3C are cross-sectional views for explaining in sequence a manufacturing process of the semiconductor device according to the embodiment of the present invention;

FIG. 4 is a flowchart showing a manufacturing process of the semiconductor device according to the embodiment of the present invention;

FIG. 5 is a flowchart showing another manufacturing process of the semiconductor device according to the embodiment of the present invention;

FIG. 6 is a cross-sectional view showing a structure of a first resin composition and a second resin composition according to the embodiment of the present invention;

FIG. 7 is a cross-sectional view showing another structure of the semiconductor device according to the embodiment of the present invention;

FIG. 8 is a cross-sectional view showing still another structure of the semiconductor device according to the embodiment of the present invention;

FIGS. 9A to 9C are cross-sectional views for explaining in sequence another manufacturing process of the semiconductor device according to the embodiment of the present invention;

FIGS. 10A and 10B are cross-sectional views showing examples of the structure of the first resin composition and the second resin composition according to the embodiment of the present invention; and

FIGS. 11A to 11C are cross-sectional views for explaining in sequence still another manufacturing process of the semiconductor device according to the embodiment of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereafter, an embodiment of the present invention will be described referring to the drawings. In all the drawings, the same constituents will be given the same numeral, and the description thereof will not be repeated.

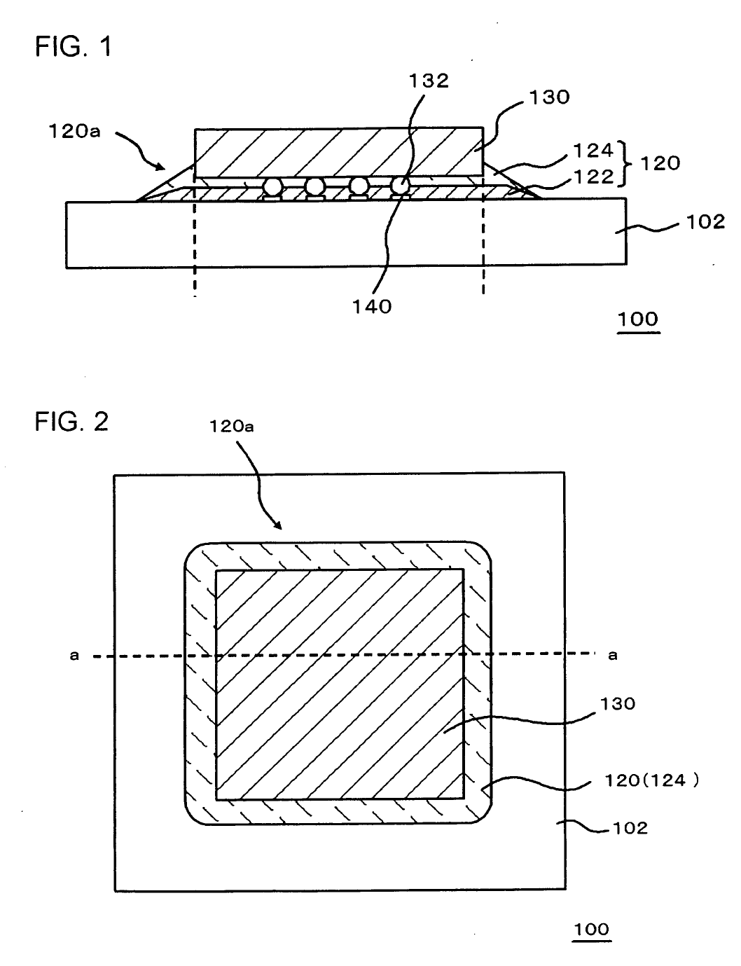

FIG. 1 is a cross-sectional view showing a structure of a semiconductor device according to an embodiment of the present invention. FIG. 2 is a plan view showing a structure of the semiconductor device according to this embodiment. FIG. 1 corresponds to the cross-sectional view taken along a line a-a in FIG. 2.

The semiconductor device 100 includes a substrate 102, a semiconductor chip 130 mounted on the substrate 102, and an underfill resin 120 formed between the substrate 102 and the semiconductor chip 130. On a surface of the substrate 102 (upper surface according to FIG. 1), pads 140 are provided. In this embodiment, the substrate 102 may be a multilayer interconnect substrate including a plurality of interconnect layers. The semiconductor chip 130 includes an element-carrying surface on which bumps 132 are provided. The bump 132 may be constituted of, for example, a solder ball. The semiconductor chip 130 is mounted on the surface of the substrate 102 such that the element-carrying surface confronts the upper surface of the substrate 102. The semiconductor chip 130 is electrically connected in a flip-chip style to the pads 140, through the bumps 132.

The underfill resin 120 is provided on the surface of the substrate 102 and between the substrate 102 and the semiconductor chip 130, and includes a filet 120a provided around the semiconductor chip 130 on the surface of the substrate 102. In this embodiment, the underfill resin 120 includes a first resin layer 122 constituted of a first resin composition and a second resin layer 124 constituted of a second resin composition, such that the first resin layer and the second resin layer are superposed on each other in at least a part of a region overlapping with the semiconductor chip 130 in a plan view.

The second resin layer 124 constitutes an upper layer over the first resin layer 122. Also, the first resin layer 122 may be formed over an area larger than a half of a region where the underfill resin 120 is in contact with the substrate 102.

In the example shown in FIG. 1, both of the first resin layer 122 and the second resin layer 124 are provided over an area including the region overlapping with the semiconductor chip 130 in a plan view and the entirety of the filet 120a. Here, substantially the entirety of the region where the substrate 102 and the underfill resin 120 are in contact is occupied with the first resin layer 122. In this example, also, the four corner portions of the semiconductor chip 130, on the side thereof confronting the substrate 102, may be covered with the second resin layer 124. Such structure enhances the bonding strength between the second resin layer 124 and the semiconductor chip 130. Also, connection points of the pad 140 and the bump 132 may be located inside the first resin layer 122.

Here, the first resin composition constituting the first resin layer 122, and the second resin composition constituting the second resin layer 124 may respectively contain, as prime materials, a resin serving as the base resin, a hardener, and a filler. The filler may be silica or alumina filler, for example.

The first resin composition and the second resin composition may be constituted of, for example, a thermosetting resin. In this case, such resins that are different in fluidity before curing (forming) or during heat-pressing for curing (forming) may be employed for the first resin composition and the second resin composition.

For example, the first resin composition and the second resin composition may have different filler contents (wt. %) with respect to the overall resin composition. Reducing the content (wt. %) of the filler leads to higher fluidity of the resin composition. A difference in filler content (wt. %) with respect to the overall resin composition between the first resin composition and the second resin composition may be, for example, 1% or higher.

For example, the first resin composition and the second resin composition may be different in average particle diameter of the filler respectively contained therein. Increasing the average particle diameter of the filler leads to higher fluidity of the resin composition. A difference in average particle diameter of the filler between the first resin composition and the second resin composition may be, for example, 5 μm or greater.

For example, also, the first resin composition the second resin composition may be different in viscosity before the curing or during the heat-pressing for curing the under fill resin. Increasing the viscosity of the resin composition facilitates forming the filet in a desired uniform shape.

Also, the first resin composition and the second resin composition may be different, for example, in glass transition temperature (Tg). A difference in glass transition temperature between the first resin composition and the second resin composition may be, for example, 5° C. or greater.

Further, the first resin composition and the second resin composition may be different, for example, in type or ratio of the prime material. The first resin composition and the second resin composition may contain, for example, different resins that serve as the base resin, or different hardeners.

Further, the first resin layer 122 and the second resin layer 124 may be different, for example, in insulating performance. For example, the first resin layer 122 and the second resin layer 124 may be formed such that at least one thereof contains conductive particles, and that the content of the conductive particles is different from each other. Also, the other of the first resin layer 122 and the second resin layer 124 may be formed without using the conductive particles.

Now, specific examples will be given hereunder about the structure of the first resin layer 122 and the second resin layer 124 according to this embodiment.

In this embodiment, the first resin layer 122 may be constituted of a material suitable for assuring the effective connection of the pad 140 of the substrate 102 and the bump 132 of the semiconductor chip 130. Also, the first resin layer 122 may be constituted of a material having a thermal expansion coefficient close to that of the substrate 102. For example, the first resin layer 122 may be constituted of a material having a glass transition temperature Tg closer to that of the substrate 102 than the second resin layer 124 is. Further, the first resin layer 122 may have higher conductivity than the second resin layer 124.

On the other hand, the second resin layer 124 may be constituted of a material suitable for assuring the effective connection of the semiconductor chip 130 and the substrate 102. The second resin layer 124 may be constituted of a material that can be easily controlled for forming the filet 120a in a uniform shape. Also, the second resin layer 124 may be constituted of a material having higher insulativeness than the first resin layer 122.

Based on the foregoing viewpoints, the first resin layer 122 may have, for example, a higher elastic modulus than that of the second resin layer 124. Such arrangement can make the first resin layer 122 harder than the second resin layer 124, thereby reinforcing the connection between the pad 140 and the bump 132. Conversely, making the second resin layer 124 softer facilitates controlling the shape of the filet 120a of the underfill resin 120.

Also, the first resin layer 122 and the second resin layer 124 may be constituted of a thermosetting resin, such that the second resin composition obtains higher fluidity than the first resin composition before the curing or during the heat-pressing for curing. To attain such structure, for example the first resin composition may have a higher filler content (wt. %) with respect to the entirety of the first resin composition, than that of the second resin composition with respect to the entirety of the second resin composition. Another example for attaining the foregoing structure is employing a filler of a smaller average particle diameter for the first resin composition, than for the second resin composition.

Also, the second resin composition may have, for example, higher viscosity before the curing of the underfill resin or during the heat-pressing for curing the underfill resin, than the first resin composition. Forming the second resin composition in higher viscosity facilitates forming the filet in a desired uniform shape.

Further, the first resin layer 122 may contain, for example, the same resin as that constituting the substrate 102, as the resin that serves as the base resin. For example, the substrate 102 may have a multilayer interconnect structure including a polyimide resin and interconnect layers sequentially stacked. In this case, the first resin layer 122 may contain the polyimide resin as the resin that serves as the base resin. Such structure can make the glass transition temperature Tg of the first resin layer 122 closer to that of the substrate 102, and the thermal expansion coefficient to that of the substrate 102. Accordingly, the underfill resin 120 and the substrate 102 exhibit similar behavior despite the expansion or contraction thereof after the curing of the underfill resin, which leads to enhancing the bonding strength between the substrate 102 and the first resin layer 122. Consequently, positional deviation between the pad 140 and the bump 132 located inside the first resin layer 122 can be suppressed despite the expansion of the substrate 102 and the underfill resin 120, and therefore effective connection between the pad 140 and the bump 132 can be secured. Also, the structure shown in FIG. 1, in which the first resin layer 122 is provided over the area including the region overlapping with the semiconductor chip 130 and the entirety of the filet 120a, mitigates the stress between the substrate 102 and the underfill resin 120, thereby further assuring the effective connection therebetween.

Meanwhile, the second resin layer 124 may contain an epoxy resin as the base resin. Employing the epoxy resin for the second resin layer 124 can make the Young's modulus of the second resin layer 124, the upper layer over the first resin layer 122, lower than that of the first resin layer 122, thereby facilitating forming the filet 120a in a desired uniform shape. Forming thus the filet 120a constituted of the second resin layer 124 in the desired uniform shape allows ensuring the adhesion of the semiconductor chip 130 and the underfill resin 120. In this example, also, the corner portions of the semiconductor chip 130 on the side confronting the substrate 102 are covered with the second resin layer 124, which further assures the adhesion between the semiconductor chip 130 and the underfill resin 120.

Further, the first resin composition may contain, for example, conductive particles. Examples of the material constituting the conductive particles include metals such as gold, silver, copper, palladium, aluminum, and nickel, and carbon-based materials. Employing such materials allows improving the electrical connection between the pad 140 and the bump 132. On the other hand, the second resin composition may be formed without using the conductive particle. In this case, the insulativeness of the second resin layer 124 can be further assured.

In this embodiment, the foregoing materials that constitute the first resin layer 122 and the second resin layer 124 may be employed in desired combinations. For example, in the case where the first resin layer 122 contains the polyimide resin containing the conductive particles as the base resin, the second resin layer 124 may contain the epoxy resin that does not contain the conductive particles, as the base resin.

Hereunder, description will be given on a manufacturing process of the semiconductor device 100 according to this embodiment.

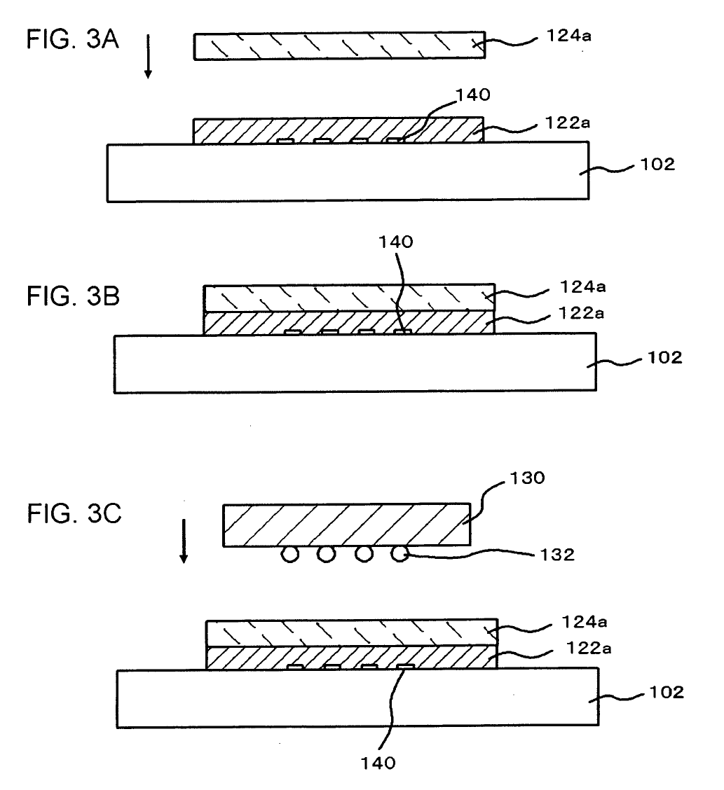

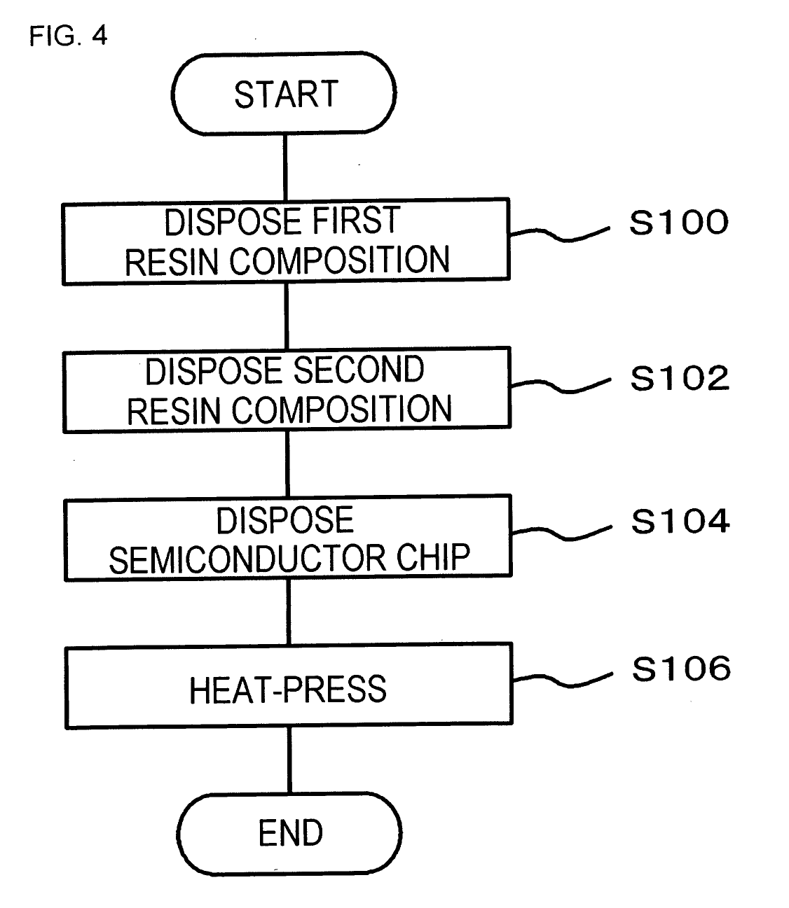

FIGS. 3A to 3C are cross-sectional views for explaining in sequence a manufacturing process of the semiconductor device 100 shown in FIGS. 1 and 2. FIG. 4 is a flowchart showing the manufacturing process of the semiconductor device 100.

The first resin composition 122a before the heat-pressing of the first resin layer 122, and the second resin composition 124a before the heat-pressing of the second resin layer 124 may be respectively prepared in various forms including a film such as a die attach film, and paste. The following description represents the case where the first resin composition 122a and the second resin composition 124a are prepared in a form of a film.

First, the first resin composition 122a is placed on the substrate 102 on which the pads 140 are provided (FIG. 3A, and step S100 in FIG. 4). Then the second resin composition 124a is placed on the first resin composition 122a on the substrate 102 (FIG. 3B, and step S102 in FIG. 4). The semiconductor chip 130 is then placed on the second resin composition 124a on the substrate 102 (FIG. 3C, and step S104 in FIG. 4). This is followed by a positioning process between the substrate 102 and the semiconductor chip 130, and a heat-pressing process from over the semiconductor chip 130 (step S106 in FIG. 4). The condition for the heat-pressing differs depending on the type of the resin composition employed, but generally may be set at approx. 20 gf/bump to 100 gf/bump in pressure, and approx. 200° C. to 300° C. in temperature.

Such process connects the bumps 132 and the pads 140, and bonds the first resin composition 122a and the second resin composition 124a to the substrate 102 and the semiconductor chip 130, respectively. Here, the heat-pressing process also bonds the first resin composition 122a and the second resin composition 124a together. Through the foregoing process, the first resin composition 122a and the second resin composition 124a are cured or formed, and the semiconductor device 100 having the structure as shown in FIG. 1 can be obtained.

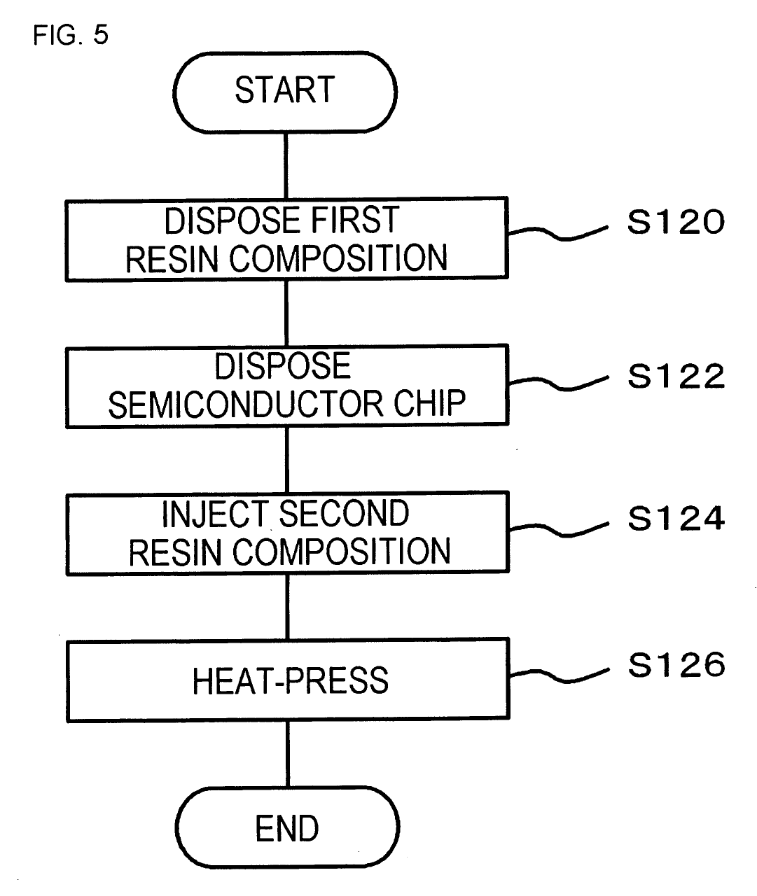

Alternatively, the second resin composition 124a constituting the upper layer may be a resin solution. In this case, although the semiconductor chip 130 may be placed on the second resin composition 124a after stacking it on the first resin composition 122a as shown in FIG. 4, a different process may be adopted, for example as the flowchart shown in FIG. 5.

In this process also, firstly the first resin composition 122a is placed on the substrate 102 on which the pads 140 are provided (step S120). Then the semiconductor chip 130 is placed on the first resin composition 122a on the substrate 102 (step S122). At this stage, a gap may be formed between the first resin composition 122a and the semiconductor chip 130. Here, the positioning between the substrate 102 and the semiconductor chip 130 is executed. Then the second resin composition 124a, which is a resin solution, is injected into between the first resin composition 122a and the semiconductor chip 130 (step S124). This is followed by the heat-pressing from over the semiconductor chip 130, as shown in FIG. 4 (step S126). Such process connects the bumps 132 and the pads 140, and bonds the first resin composition 122a and the second resin composition 124a to the substrate 102 and the semiconductor chip 130, respectively. Here, the heat-pressing process also bonds the first resin composition 122a and the second resin composition 124a together. Thus, the first resin composition 122a and the second resin composition 124a are cured or formed, and the semiconductor device 100 having the structure as shown in FIG. 1 can be obtained.

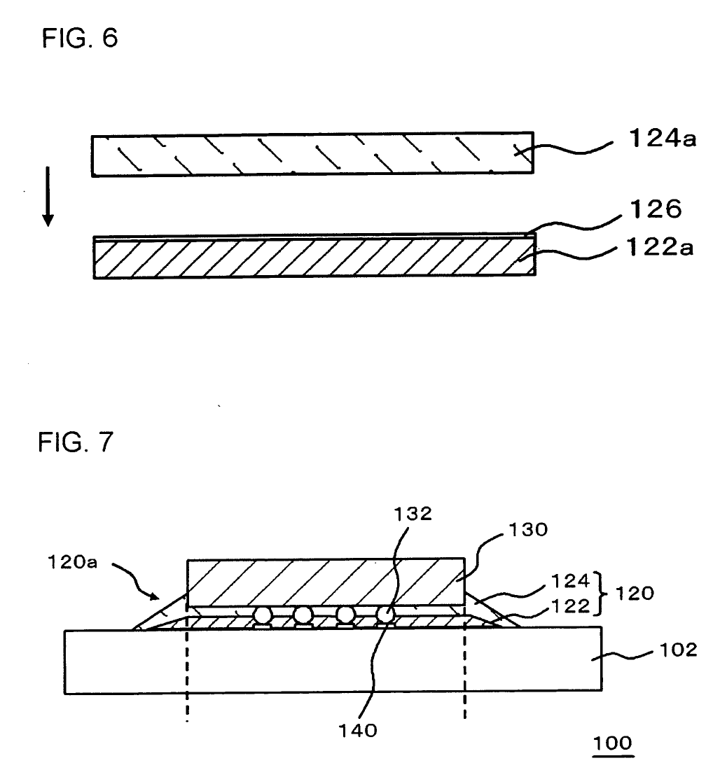

As shown in FIG. 6, an adhesive 126 may be provided between the first resin composition 122a and the second resin composition 124a before the heat-pressing process, to thereby form a two-layer film. In this case, the semiconductor chip 130 may be mounted on those resin compositions after mounting them on the substrate 102, and then the heat-pressing may be executed. Such process also provides the semiconductor device 100 having the structure as shown in FIG. 1.

For example, a film containing an epoxy resin as the base resin, such as T693/R6000 series manufactured by Nagase ChemteX Corporation, a paste such as T693/UFR series manufactured by Nagase ChemteX Corporation, and a resin solution such as T693/R3000 series manufactured by Nagase ChemteX Corporation may be employed for the second resin composition 124a. For the first resin composition 122a, for example a polyimide-based film such as DF series manufactured by Hitachi Chemical Co., Ltd. may be employed.

Also, though the first resin layer 122 is also provided over the area including the region overlapping with the semiconductor chip 130 and the entirety of the filet 120a in the example shown in FIG. 1, the first resin layer 122 may be formed in a region corresponding to only a part of the filet 120a, as shown in FIG. 7. In this case also, the first resin layer 122 is provided over the entirety of the region overlapping with the semiconductor chip 130 in a plan view. In such structure, also, the majority of the region where the underfill resin 120 is in contact with the substrate 102 is occupied with the first resin layer 122, and the connection points between the pad 140 and the bump 132 are located inside the first resin layer 122. Accordingly, the advantages offered by the structure shown in FIG. 1 can be equally obtained.

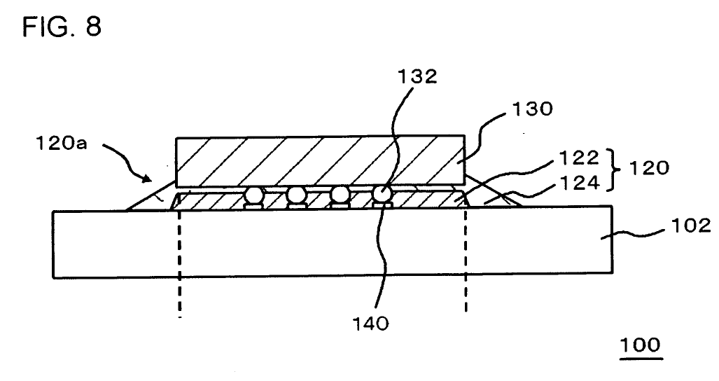

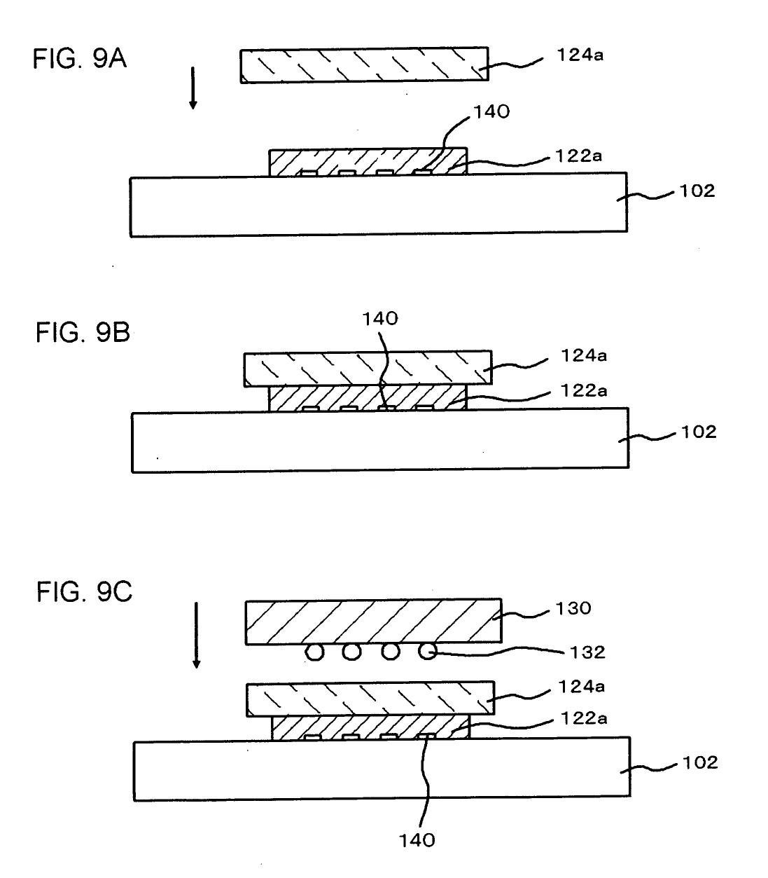

FIGS. 8 and 9A to 9C illustrate another example of the structure of the semiconductor device 100 according to this embodiment. FIG. 8 is a cross-sectional view of the semiconductor device 100, and FIGS. 9A to 9C are cross-sectional views for explaining in sequence the manufacturing process of the semiconductor device 100 shown in FIG. 8.

This example is different from the structure shown in FIG. 1 in that the first resin layer 122 of the underfill resin 120 is only provided in the region overlapping with the semiconductor chip 130, and barely provided in the region corresponding to the filet 120a.

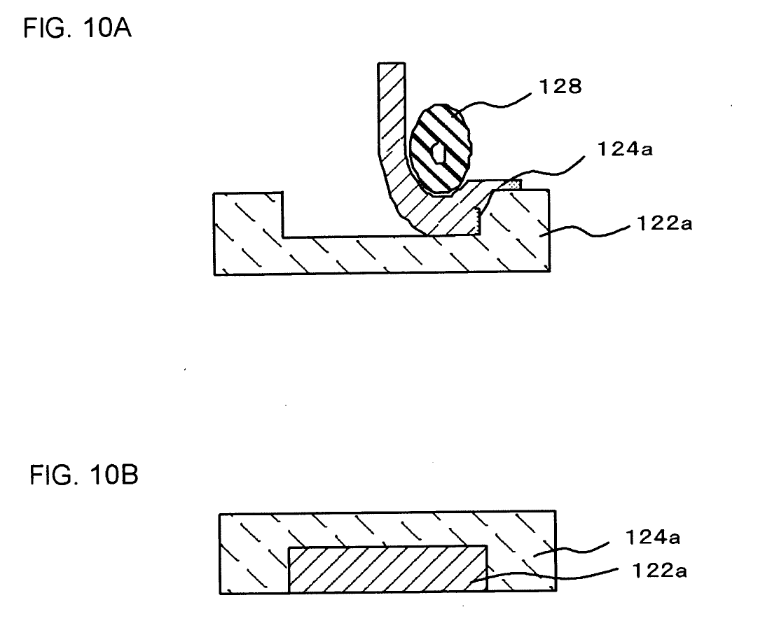

The semiconductor device 100 thus configured can be obtained for example by forming the first resin layer 122 in a smaller size than the second resin layer 124, as shown in FIGS. 9A to 9C. Also, as shown in FIG. 10A, the second resin composition 124a, for example of a paste form, may be squeezed by a roll 128 into a recess formed on the first resin composition 122a, for example of a film form, and a unified type resin composition may be formed by heat-pressing as shown in FIG. 10B. Then the semiconductor device 100 of the structure shown in FIG. 8 can also be obtained by placing the resin composition thus formed on the substrate 102 in the same way as FIG. 9B, and placing the semiconductor chip 130 on the resin composition and executing the heat-pressing.

The semiconductor device 100 and the manufacturing method thereof according to this embodiment offer the following advantageous effects.

In the foregoing semiconductor device 100, the second resin layer 124 is formed over the area including the filet 120a and the region overlapping with the semiconductor chip 130 in a plan view. Such structure allows dispersing, in an in-plane direction of the substrate, the stress of the second resin layer 124 arising from expansion or contraction of the substrate 102 and the semiconductor chip 130 after the curing of the underfill resin 120, in the case where an appropriate material for forming the filet in a desirable shape is employed for the second resin layer 124. Meanwhile regarding the first resin layer 122, for example employing a material having a thermal expansion coefficient close to that of the substrate 102 enables enhancing the bonding strength between the substrate 102 and the semiconductor chip 130. Consequently, the foregoing structure allows, in the flip-chip connection of the semiconductor chip 130 to the substrate 102, achieving an optimal balance between obtaining sufficient bonding strength and stably forming the filet of the semiconductor chip 130 in a uniform shape.

In this embodiment, also, the four corner portions of the semiconductor chip 130 on the side confronting the substrate 102 are covered with the second resin layer 124. Accordingly, the corner portions are free from an interface between the plurality of resin layers, which contributes to enhancing the bonding strength between the second resin layer 124 and the semiconductor chip 130.

Also, the connection points between the pad 140 and the bump 132 are located inside the first resin layer 122. Therefore the first resin layer 122 serves to assure the effective connection of the pad 140 and the bump 132. The electrical connection between the pad 140 and the bump 132 can also be assured by, for example, providing a material containing conductive particles in the first resin layer 122.

Further, in order to enhance the bonding strength between the substrate 102 and the semiconductor chip 130 through the foregoing process, the heat-pressing has to be executed under a high pressure. However, increasing the pressure urges the filet 120a to creep upward to the upper surface of the semiconductor chip 130, thereby making it difficult to form the filet 120a in a uniform shape. In this embodiment, however, since a material that facilitates controlling the shape of the filet is employed for the second resin layer 124, the filet 120a can be formed in a uniform shape.

Stabilizing the shape of the filet allows improving the reliability (temperature cycle resistance). Also, suppressing the filet from excessively spreading leads to improvement in mounting efficiency.

Forming a narrow gap between the semiconductor chip and the substrate may make it difficult to fill the gap with the underfill resin, however locating the first resin composition 122a and the second resin composition 124a on the substrate 102 as shown in FIG. 4 before mounting the semiconductor chip 130 allows eliminating such disadvantage and assuring optimal formation of the underfill resin.

Although the embodiment of the present invention has been described in details as above referring to the drawings, the embodiment is only exemplary and various other structures may be adopted in the scope of the present invention.

One of the first resin composition 122a and the second resin composition 124a may be constituted of a thermosetting resin, and the other may be constituted of a thermoplastic resin. For example, the thermosetting resin may be employed for the first resin layer 122, and the thermoplastic resin for the second resin layer 124. In this case, the second resin composition 124a obtains higher fluidity than that of the first resin composition 122a.

Although the underfill resin 120 contains two types of resin layers in the foregoing embodiment, the underfill resin 120 may contain three or more types of resin layers. In this case also, the underfill resin 120 can equally be cured by executing the heat-pressing process with the resin compositions constituting the respective resin layers stacked on each other.

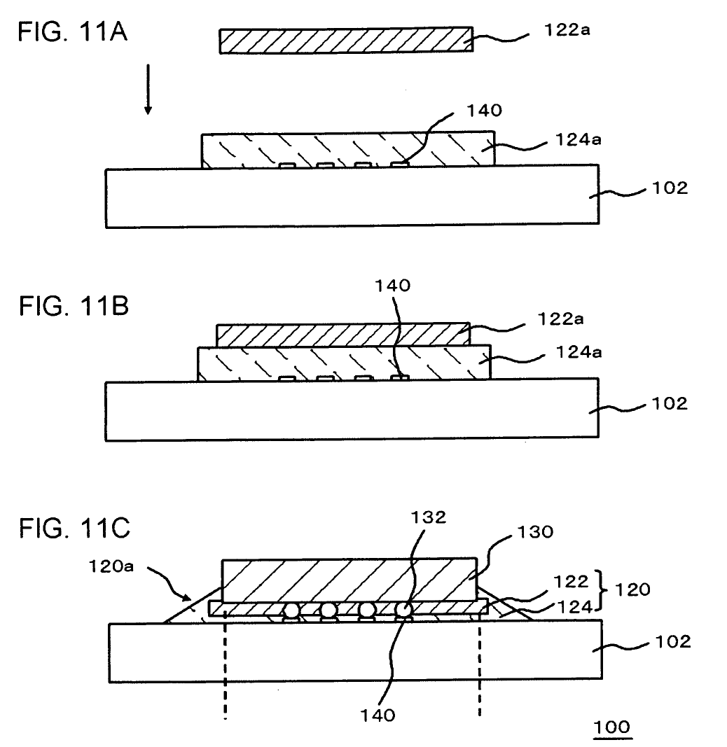

Also, although the foregoing embodiment exemplifies the case where the second resin layer 124 is provided on top of the first resin layer 122, the first resin layer 122 may constitute the upper layer over the second resin layer 124. FIGS. 11A to 11C are cross-sectional views for explaining in sequence a manufacturing process of the semiconductor device 100 thus configured. Such structure can also be obtained through the same manufacturing process as that described referring to FIGS. 3A to 3B and FIG. 4.

In the foregoing structure also, the second resin layer 124 may be formed over the area including the filet 120a and the region overlapping with the semiconductor chip 130 in a plan view. Such structure allows dispersing, in an in-plane direction of the substrate, the stress of the second resin layer 124 arising from expansion or contraction of the substrate 102 and the semiconductor chip 130 after the curing of the underfill resin 120, in the case where an appropriate material for forming the filet in a desirable shape is employed for the second resin layer 124. Meanwhile regarding the first resin layer 122, for example employing a material having a thermal expansion coefficient close to that of the substrate 102 enables enhancing the bonding strength between the substrate 102 and the semiconductor chip 130. Consequently, the foregoing structure allows, in the flip-chip connection of the semiconductor chip 130 to the substrate 102, achieving an optimal balance between obtaining sufficient bonding strength and stably forming the filet of the semiconductor chip 130 in a uniform shape.

Such structure offers further advantage that the first resin layer 122 serves as a block that prevents the second resin composition 124a from creeping upward to the surface of the semiconductor chip 130 opposite to the surface thereof confronting the substrate 102 (upper surface according to the drawings), during the formation of the filet 120a of the second resin composition 124a. This leads to stabilization of the shape of the filet, and to improvement in reliability (temperature cycle resistance). Also, suppressing the filet from excessively spreading leads to improvement in mounting efficiency.

It is apparent that the present invention is not limited to the above embodiment, and may be modified and changed without departing from the scope and spirit of the invention.

What is claimed is:

1. A semiconductor device, comprising:
a substrate with a pad formed on a surface thereof;
a semiconductor chip mounted on said surface of said substrate such that an element-carrying surface thereof on which a bump is provided confronts said surface, and connected in a flip-chip style to said pad through said bump; and
an underfill resin formed on said surface of said substrate in a region between said surface of said substrate and said semiconductor chip, and including a filet formed around said semiconductor chip on said surface of said substrate;
wherein said underfill resin includes a first resin layer constituted of a first resin composition and a second resin layer constituted of a second resin composition; said first resin layer and said second resin layer being superposed on each other in at least a part of a region overlapping with said semiconductor chip in a plan view; and at least one of said first resin layer and said second resin layer is formed over an area including said region overlapping with said semiconductor chip in a plan view and said filet.

2. The semiconductor device according to claim 1,
wherein said first resin layer and said second resin layer constituting said underfill resin are provided over an entirety of said region overlapping with said semiconductor chip in a plan view.

3. The semiconductor device according to claim 1,
wherein said second resin layer constitutes an upper layer over said first resin layer; and
said second resin layer is provided over an area including said region overlapping with said semiconductor chip in a plan view and said filet.

4. The semiconductor device according to claim 3,
wherein said second resin layer is provided so as to cover four corner portions of said semiconductor chip on a side of said semiconductor chip confronting said surface of said substrate.

5. The semiconductor device according to claim 1,
wherein said first resin layer has a higher elastic modulus than that of said second resin layer.

6. The semiconductor device according to claim 1,
wherein said first resin composition and said second resin composition are a thermosetting resin; and
said second resin composition has higher fluidity than that of said first resin composition, before a curing process or in a heat-pressing process for curing.

7. The semiconductor device according to claim 1,
wherein a filler content (wt. %) of said first resin composition with respect to an entirety thereof is higher than that of said second resin composition with respect to an entirety of said second resin composition.

8. The semiconductor device according to claim 1,
wherein said first resin composition contains a conductive particle.

9. The semiconductor device according to claim 1,
wherein the other of said first resin layer and said second resin layer is also provided over at least a part of an area including said region overlapping with said semiconductor chip in a plan view and said filet.

10. A method of manufacturing said semiconductor device according to claim 1, comprising:
disposing on said surface of said substrate one of said first resin composition to constitute said first resin layer and said second resin composition to constitute said second resin layer, the other of said first resin composition and said second resin composition, and said semiconductor chip, such that said one of said first resin composition and said second resin composition, the other thereof, and said semiconductor chip are to be stacked in this order; and
connecting said pad of said substrate and said bump of said semiconductor chip by heat-pressing, and curing said first resin composition and said second resin composition thereby forming said underfill resin.

11. The method according to claim 10,
wherein one of said first resin composition and said second resin composition is a film or a paste;
the other of said first resin composition and said second resin composition is a film, a paste, or a resin solution; and
said disposing includes:
disposing said one of said first resin composition and said second resin composition on said surface of said substrate;
disposing the other of said first resin composition and said second resin composition on said one of said first resin composition and said second resin composition on said surface of said substrate; and
disposing said semiconductor chip on the other of said first resin composition and said second resin composition on said surface of said substrate.

12. The method according to claim 10,
wherein one of said first resin composition and said second resin composition is a film or a paste;
the other of said first resin composition and said second resin composition is a resin solution; and
said disposing includes:
disposing said one of said first resin composition and said second resin composition on said surface of said substrate; disposing said semiconductor chip on said one of said first resin composition and said second resin composition on said surface of said substrate; and
injecting the other of said first resin composition and said second resin composition into between said semiconductor chip and said one of said first resin composition and said second resin composition.
